(19) United States
(12) Patent Application Publication
(10) Pub. No.: US 2004/0115348 A1
(43) Pub. Date: Jun. 17, 2004

(54) Method for processing silicon-carbide preforms having a high temperature boron nitride coating

(76) Inventors: Dennis James Landini, Newark, DE (US); Roger Lee Ken Matsumoto, Newark, DE (US)

Correspondence Address: NIXON & VANDERHYE P.C./G.E., 1100 N. GLEBE RD., SUITE 800, ARLINGTON, VA, 22201, US

(21) Appl. No.: 10/317,191

(22) Filed: Dec. 12, 2002

(51) Int. Cl. C23C 16/32

(52) U.S. Cl. 427/249.15; 427/249.2; 427/255.12

(57) ABSTRACT

A method of processing a ceramic preform is disclosed having the steps of: coating with a preceramic polymer at least one fabric panel formed of silicon carbide fibers coated with a high temperature boron nitride; shaping the at least one fabric panel into a preliminary preform; curing the preceramic polymer to impart rigidity to the preform, and inserting the rigidized preform into a reactor without tooling for a chemical vapor infiltration process to form the ceramic preform.

### BACKGROUND OF THE INVENTION

This invention relates to techniques for producing silicon-carbide (SiC) preforms with a boron nitride (BN) coating in a chemical vapor infiltration (CVI) reactor.

Silicon Carbide/Silicon Carbide (SiC/SiC) ceramic-matrix-composite (CMC) products are conventionally processed using a chemical vapor infiltration (CVI) reactor. High temperature Boron nitride (BN) is used as an interface coating for SiC/SiC CMC products. BN coats the fibers of the SiC substrate. A SiC outer coating is applied to the BN coated SiC fibers. The BN interface coating provides a layer between the underlying SiC fiber and the outer ceramic SiC coating. High temperature BN is crystalline and stable, especially as compared to the stability of low temperature amorphous BN. Crystalline BN tends to retain its stability in moisture rich environments, such as exists in a high temperature combustion exhaust flow path.

Conventional processing techniques for SiC/SiC CMC products involve tooling a SiC fiber preform and applying a low temperature BN coating via CVI to rigidize the preform. The tooling can then be removed from the reactor and a subsequent CVI SiC protective coating can be applied to the BN coated fiber preform. However, CMC processing by this approach limits the user to a lower temperature CVI BN coating to rigidize the part and results in a substantial portion of the reactor chamber be filled with graphite tooling. The region within the chamber available for the preform is reduced due to the presence of the tools.

In the past, SiC fiber sheets with high temperature BN coatings have been cut and assembled as a preform to the extent practical with the flexible sheets. However, rigidizing the sheets into a final preform still required tooling the sheets and applying either a low temperature CVI BN followed by a CVI SiC protective coating, or skipping the CVI BN step and applying a CVI SiC directly over the high temperature BN coated fabric while still in the tooling.

Tooling, e.g., a press for the sheets, is applied in the CVI reactor because the preform does not become rigid until after being processed in the reactor chamber. The preform is made of flexible fabric sheets of SiC fibers. The high temperature BN coating applied to the SiC fibers in the fabric sheets does not make the sheets rigid. Thus, the partially formed preform that is formed of the sheets is not rigid when placed in the CVI reactor.

The presence of tooling and excess material in the reactor reduces the available space in the reactor for the preform, obstructs the coating process of preform in the reactor, and adds additional cost to the product. Accordingly, there is a long felt need for a CVI process that treats SiC preforms coated with high temperature BN without applying tooling to the preform in the CVI reactor.

### BRIEF DESCRIPTION OF THE INVENTION

In a one embodiment the invention is method of processing a ceramic preform comprising: coating with a preceramic polymer at least one fabric panel formed of silicon carbide fibers coated with a high temperature boron nitride; shaping the fabric panel into a preliminary preform; curing the preceramic polymer to impart rigidity to the shaped fabric panel preform, and processing the preform without tooling in a chemical vapor infiltration process to form the ceramic preform.

In a second embodiment the invention is a method of processing a ceramic preform comprising: coating with a preceramic polymer at least one fabric panel formed of silicon carbide fibers coated with a high temperature boron nitride; shaping the fabric panel into a preliminary preform shape; heating the preceramic polymer to cure the polymer and impart rigidity to the shaped fabric panel; placing the rigid preform without tooling in a chemical vapor infiltration reactor, and coating the preform with silicon carbide in a reactor to form the ceramic preform.

### BRIEF DESCRIPTION OF THE DRAWINGS

FIG. 1 is a schematic diagram of the processing steps for processing SiC panels into a SiC/SiC ceramic preform product.

### DETAILED DESCRIPTION OF THE INVENTION

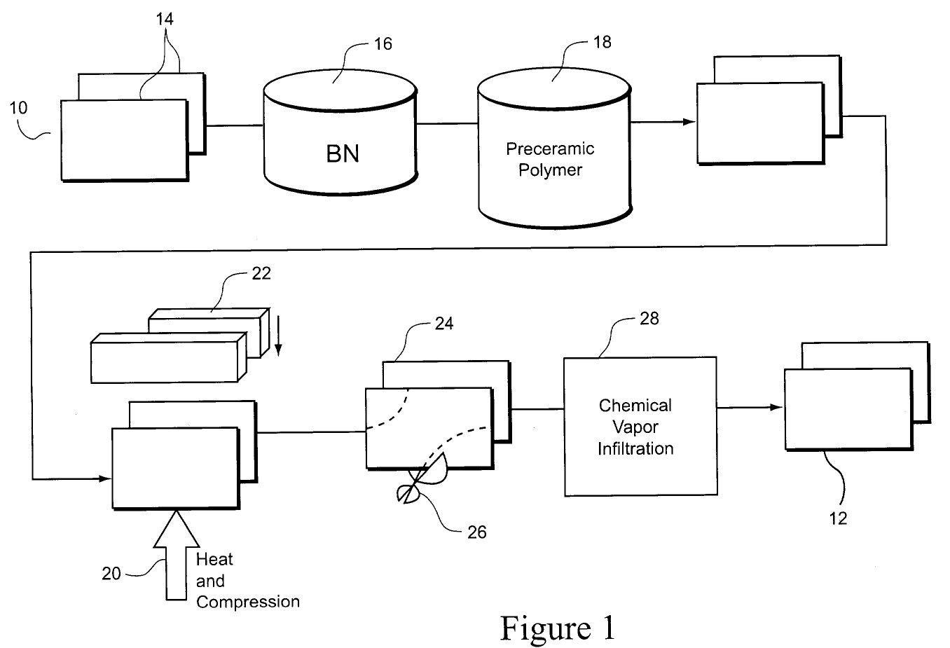

FIG. 1 is a flow chart showing exemplary process steps for forming a silicon carbide (SiC) refractory preform material, such as a ceramic fiber reinforced ceramic-matrix composite material. The flow chart shows schematically a system for applying a preceramic polymer to a SiC fiber cloth coated with BN, forming and curing the cloth into a rigid preform, and processing the preform with chemical vapor infiltration to apply a ceramic SiC coating.

A preform 10 is a matrix of ceramic fibers having a relatively porous structure and is processed using the system shown herein. At the end of the process, the preform is the final silicon carbide/silicon carbide (SiC/SiC) CMC preform product 12. It may undergo subsequent fabrication steps before the preform product becomes a final product ready for delivery to a customer or used in a larger product. The preform product may be a porous fibrous product shaped as a gas turbine shroud, combustion liner or turbine blade.

The preform product 12 may be formed into a variety of components and replacement components. One potential application is to fabricate components from the preform for a Brayton or Stirling cycle engine, which components are conventionally made from high temperature cobalt-or nickel-containing alloys.

The ceramic fiber plys 14 may include unidirectional SiC fibers, two-dimensional (2-D) woven SiC fiber tows, or three-dimensional (3-D) woven or braided SiC fiber tows. The ceramic fabric plys 14 may be assembled as a preform 10 having eight plys of SiC fibers coated with BN. The SiC fibers are coated with a high temperature BN coating 16.

The ceramic fiber plys are impregnated with a preceramic polymer 18, such as a liquid polysilazane that is sold commercially as Ceraset-SZ™ by GE Power Systems; Power Systems Composites, Diamond State Industrial Park, 400 Bellevue Road, Newark, Del. 19713. Polysilazane may be cured by thermosetting to impart rigidity to the fiber. Further, cured polysilazane may be pyrolyzed to silicon carbide or silicon nitride by heating.

The preceramic polymer 18 allows the ceramic fabric plys 14 to be cured so that the preform 10 becomes rigid. The preceramic polymer coated plys 14 are cured by thermosetting 20. The plys may also be compressed by aluminum plates 22 that press the plys together during curing. When cured, the fiber plys 14 in the preform 10 are rigid and form a shape 24 similar to the desired preform. Once cured, the rigid panels 24 may be further shaped by machining 26. Machining, e.g., drilling, milling and cutting, removes excess SiC panel material from the rigid preform 26. At the completion of the machining, the rigid preform 24 has the shape of the preliminary preform and is ready for the CVI process. The machining and its associated tooling may be outside of a CVI reactor.

The rigid preliminary preform 24 is positioned in a reaction chamber 28 for chemical vapor infiltration (CVI). The preform is partially densified by the CVI process, with a suitable ceramic material, e.g. SiC, to yield a rigid final preform 12 having a relatively large volume fraction of interconnected pores. The material use for CV infiltration may be SiC, Si₃N₄, refractory disilicide or another suitable infiltration material.

The CVI process coats the ceramic fibers of the plys of the preform 24 with a generally uniform coating of ceramic material, e.g. SiC. The ceramic coating applied in the reactor provides an overcoat to the BN coating on the ceramic fibers in the panels that make up the preform. The ceramic coating of the fibers provides further rigidity to the preform, and shields the fibers from damage during subsequent processing steps after CVI processing. After CVI 28, the final preform 12 is somewhat denser as it has been transformed into a SiC/SiC material, such as a fiber reinforced ceramic matrix composite (CMC)material.

The method disclosed here may be used to form ceramic bodies or composite bodies made by reaction-bonded silicon carbide, by ceramic polymer precursors, or by other processes that produce a material that is porous and may be densified by the reaction forming process disclosed here.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of processing a ceramic preform comprising:
coating with a preceramic polymer at least one fabric ply formed of ceramic fibers coated with a high temperature boron nitride;
shaping the fabric ply into a preliminary preform;
curing the preceramic polymer to impart rigidity to the preliminary preform, and
inserting the rigid preliminary preform into a reactor for a chemical vapor infiltration process to form the ceramic preform.

2. A method as in claim 1 wherein the ceramic fibers are silicon carbide fibers.

3. A method as in claim 1 wherein the preliminary preform is coated with a ceramic SiC coating during the chemical vapor infiltration process.

4. A method as in claim 1 wherein the at least one fabric ply is an eight ply panel of silicon carbide fibers.

5. A method as in claim 1 wherein the shaping of the at least one fabric ply includes cutting the ply.

6. A method as in claim 1 wherein the ceramic fibers of the at least one fabric ply are arranged in a two-dimensional woven fiber tow.

7. A method as in claim 1 wherein the ceramic fibers of the at least one fabric ply are arranged in a three-dimensional woven fiber tow.

8. A method as in claim 1 wherein the rigid preliminary preform has a porosity in a range of 10 percent of the preform volume to 45 percent by volume prior to chemical vapor infiltration.

9. A method as in claim 1 wherein the chemical vapor infiltration process uses a material selected from a group comprising SiC, Si₃N₄ and refractory disilicide.

10. A method as in claim 1 wherein the preceramic polymer is a liquid polysilazane.

11. A method as in claim 1 wherein the preceramic polymer is cured by thermosetting.

12. A method of processing a ceramic preform comprising:
coating with a preceramic polymer at least one fabric ply formed of silicon carbide fibers coated with a high temperature boron nitride;
shaping the fabric ply into a preliminary preform;
heating the preceramic polymer to cure the polymer and impart rigidity to the shaped preliminary preform ;
placing the rigid preliminary preform in a chemical vapor infiltration reactor, and
during a chemical vapor infiltration process, coating the rigid preliminary preform with silicon carbide in the reactor to form the ceramic preform.

13. A method as in claim 12 wherein the rigid preform is coated with a ceramic coating during the chemical vapor infiltration process.

14. A method as in claim 12 wherein the at least one fabric ply is an eight ply panel of silicon carbide fibers.

15. A method as in claim 12 wherein the shaping of the at least one fabric ply includes cutting the panel.

16. A method as in claim 12 wherein the silicon carbide fibers of the at least one fabric ply are arranged in a two-dimensional woven fiber tow.

17. A method as in claim 12 wherein the silicon carbide fibers of the at least one fabric ply are arranged in a three-dimensional woven fiber tow.

18. A method as in claim 12 wherein the preliminary preform has a porosity is a range of 10 percent of the preform volume to 45 percent by volume prior to chemical vapor infiltration.

19. A method as in claim 12 wherein the chemical vapor infiltration process uses a material selected from a group comprising SiC, Si₃N₄ and refractory disilicide.

20. A method as in claim 12 wherein the preceramic polymer is a liquid polysilazane.

21. A method as in claim 12 wherein the preceramic polymer is cured by thermosetting.
